(19) United States
(12) Patent Application Publication
(10) Pub. No.: US 2018/0235074 A1
(43) Pub. Date: Aug. 16, 2018

(54) RADIATIVE COOLING STRUCTURE FOR PRINTED CIRCUIT

(71) Applicant: Amazing Cool Technology Corp, Taipei City (TW)

(72) Inventors: Yang-Ming SHIH, Taipei City (TW); Hung-Yun Hsu, Taipei City (TW)

(21) Appl. No.: 15/861,676

(22) Filed: Jan. 4, 2018

(30) Foreign Application Priority Data
Feb. 10, 2017 (TW) 106201975

(51) Int. Cl. H05K 1/02

(52) U.S. Cl. CPC H05K 1/0206; H05K 2201/06

(57) ABSTRACT

A radiative cooling structure for a printed circuit includes a circuit board and a cooling structure. A printed circuit is disposed on the circuit board. The printed circuit includes a plurality of printed leads and a thermal conductive area. The printed leads are connected to the thermal conductive area. A cooling structure covers the thermal conductive area. The cooling structure covers the thermal conductive area, and the cooling structure incudes a thermal radiation layer. Heat generated by heat sources on the circuit board is transferred to the thermal conductive area via the printed circuit. The cooling structure radiates the heat into surrounding space by radiation.

### TECHNICAL FIELD

The present invention relates to a radiator and, in particular, to a radiative cooling structure for a printed circuit.

### BACKGROUND

A conventional heat sink for electronic devices typically directly contacts a heat source. A chip on a circuit board is a common heat source. Therefore, the heat sinks are arranged in association with the arrangement of chips. The arrangement of the chips will affect a circuit layout, and a bad circuit layout will cause high temperature during circuit operation.

In order to solve the above-mentioned problems, a commonly-used solution utilizes heat conductive tubes, metal plates, or metal foil sheets arranged between the heat sinks and the heat source, so as to connect the heat sinks and the heat source. However, such configuration occupies more space, and the total weight increases, and consequently, the electronic device is huge and heavy. In order to reduce the space occupied by the heat conductive tubes, flat heat conductive pipes which are costly are used instead. Therefore, it is impossible for a conventional cooling system to at the same time take into account a heat dissipation efficiency issue, size, weight, and costs. As a result, the conventional cooling system is not a perfect solution and needs to improve.

In view of this, the inventor studied various technologies and created an effective solution in the present disclosure.

### SUMMARY

The present invention provides a radiative cooling structure for a printed circuit. The radiative cooling structure covers the printed circuit.

The present invention provides a radiative cooling structure for a printed circuit. The radiative cooling structure includes a circuit board and a cooling structure. A printed circuit is disposed on the circuit board. The printed circuit includes a plurality of printed leads and a thermal conductive area. The printed leads are connected to the thermal conductive area. The cooling structure covers the thermal conductive area. The cooling structure includes a thermal radiation layer.

According to the present invention, in the radiative cooling structure for the printed circuit, an adhesive layer is sandwiched between the thermal radiation layer and the circuit board.

According to the present invention, in the radiative cooling structure for the printed circuit, the thermal radiation layer is in a sheet form and consists of a thermal radiation material. The thermal radiation layer can consist of a graphene sheet or consist of a single graphene sheet. The thermal radiation layer can also consist of a plurality of graphene sheets joined together to extend.

According to the present invention, in the radiative cooling structure for the printed circuit, the thermal radiation layer includes a fixing structure and a plurality of thermal radiation particles scattered and embedded in the fixing structure. The thermal radiation particle can be a graphene fragment. Alternatively, the thermal radiation particle can be a nano-carbon ball. The fixing structure consists of a cured gel material.

According to the present invention, in the radiative cooling structure for the printed circuit, the thermal conductive area is a ground of the printed circuit. The thermal conductive area is exposed from one surface of the circuit board.

According to the present invention, in the radiative cooling structure for the printed circuit, at least one heat source is disposed on the circuit board, and the printed leads are connected between the thermal conductive area and any of the heat sources.

In the radiative cooling structure of the present invention, the printed circuit is used to replace conventional heat conductive tubes for heat transfer. Heat generated from each heat source on the circuit board is conducted to the thermal conductive area via the printed circuit. The cooling structure on the thermal conductive area then radiates the heat into surrounding space. As a result, the heat can be transferred and dissipated away without the use of additional heat conductive elements and the need of changing circuit layouts.

### BRIEF DESCRIPTION OF THE DRAWINGS

The disclosure will become more fully understood from the detailed description and the drawings given herein below for illustration only, and thus does not limit the disclosure, wherein:

FIG. 1 is a schematic view illustrating a radiative cooling structure for a printed circuit according to one embodiment of the present invention;

FIG. 2 is a cross-sectional view illustrating the radiative cooling structure for the printed circuit according to one embodiment of the present invention;

FIG. 3 is a cross-sectional view illustrating the radiative cooling structure for the printed circuit according to another embodiment of the present invention; and

FIG. 4 is a cross-sectional view illustrating the radiative cooling structure for the printed circuit according to still another embodiment of the present invention.

### DETAILED DESCRIPTION

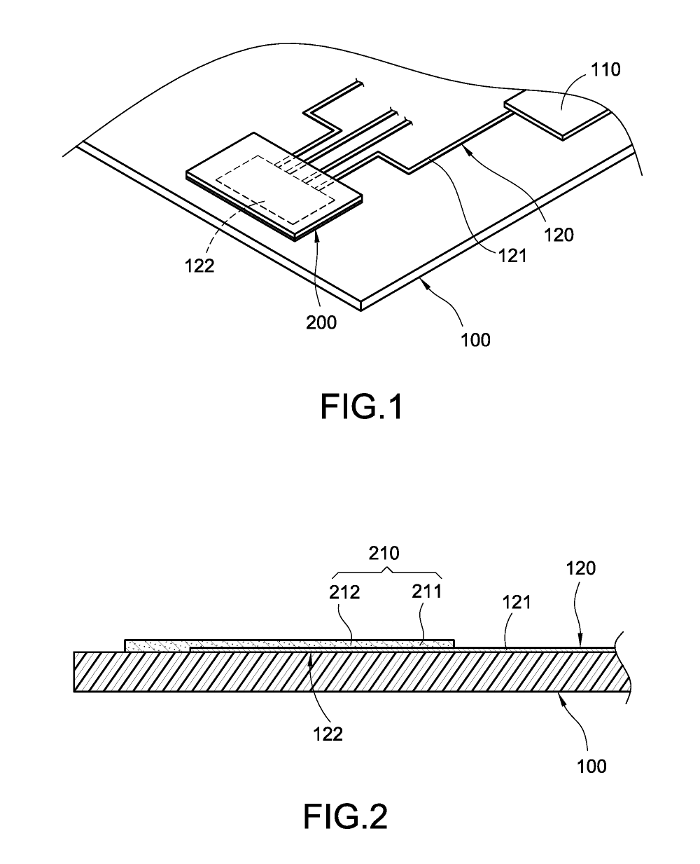

Referring to FIGS. 1 and 2, a radiative cooling structure 200 for a printed circuit 120 is provided according to one embodiment of the present invention. The radiative cooling structure 200 includes a circuit board 100 and a cooling structure 200.

At least one heat source 110 is disposed on the circuit board 110, and a printed circuit 120 is disposed on the circuit board 100. The printed circuit 120 includes a plurality of printed leads 121 and a thermal conductive area 122. The printed leads 121 are connected between the thermal conductive area 122 and any heat source 110. The printed leads 121 can be disposed inside the circuit board 110 or on a surface of the circuit board 110. The thermal conductive area 122 is exposed from one surface of the circuit board 100. The printed leads 121 in the printed circuit 120 are connected to a ground of the printed circuit 120. The ground is usually on one surface of the circuit board 100. In this embodiment, a metal covering area at the ground is enlarged to form the thermal conductive area 122.

The cooling structure 200 covers the thermal conductive area 122. The cooling structure 200 includes a thermal radiation layer 210. In the present embodiment, the thermal radiation layer 210 includes a fixing structure 211 and a plurality of thermal radiation particles 212 scattered and embedded in the fixing structure 211. The fixing structure 211 is a cured gel material. The thermal radiation particle 212 is a graphene fragment or a nano-carbon ball. Graphene is a single layer of carbon atoms arranged in a hexagonal lattice. The nano-carbon ball consists of carbon atoms arranged in a ball shape. Both the graphene and nano-carbon ball have good thermal radiation properties. The thermal radiation particles 212 are mixed with the gel material of liquid form in advance, so that the thermal radiation particles 212 are evenly dispersed inside the gel material. Then, by coating, spraying, or printing, the mixture of the thermal radiation particles 212 and the liquid-form gel material covers the thermal conductive area 122. When the gel material is cured to form the fixing structure 211, the cooling structure 200 is fixed to cover the thermal conductive area 122.

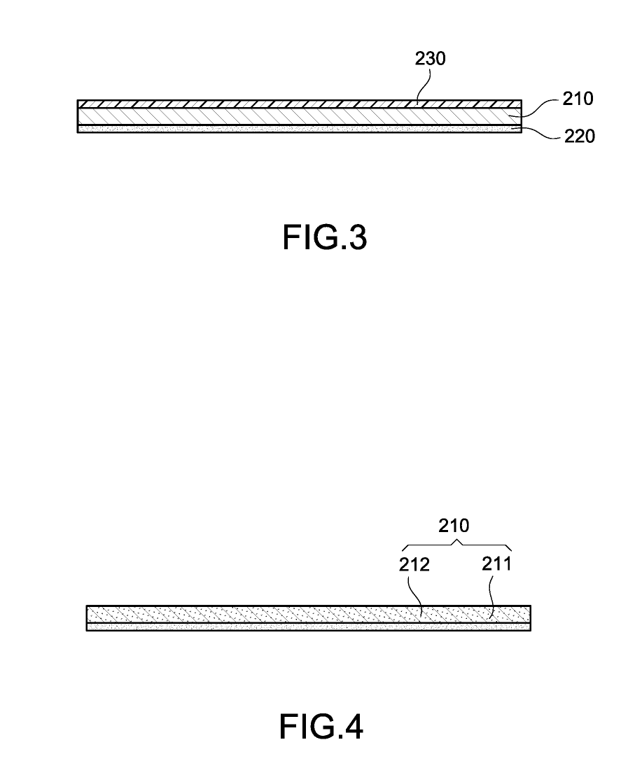

Please refer to FIG. 3 illustrating the cooling structure 200 according to another embodiment. The thermal radiation layer 210 is in a sheet form and consists of a thermal radiation material. The thermal radiation layer 210 preferably consists of a graphene sheet. The thermal radiation layer 210 can consist of a single graphene sheet or can consist of a plurality of graphene sheets joined to each other to extend. An adhesive layer 220 is sandwiched between one side of the thermal radiation layer 210 and the circuit board 100. The thermal radiation layer 210 is fixed to a surface of the circuit board 100 by means of the adhesive layer 220 to cover the thermal conductive area 122. Furthermore, the other side of the thermal radiation layer 210 can be covered by a protection layer 230 to protect the graphene sheet. The protection layer 230 preferably consists of plastic.

Please refer to FIG. 4 illustrating the cooling structure 200 according to still another embodiment of the present invention. The thermal radiation layer 210 includes a fixing structure 211 and a plurality of thermal radiation particles 212 scattered and embedded in the fixing structure 211. The fixing structure 211 consists of a cured gel material. The thermal radiation particles 212 can be graphene fragments or nano-carbon balls. The thermal radiation particles 212 are mixed with the gel material of liquid form so that the thermal radiation particles 212 are evenly dispersed inside the gel material. Then, by coating, spraying, or printing, the mixture of the thermal radiation particles 212 and the liquid-form gel material covers an adhesive layer 220. When the gel material is cured to form the fixing structure 211, the cooling structure 200 becomes an adhesive sheet, and then is adhered to the thermal conductive area 122 to cover the same.

In the radiative cooling structure 200 for the printed circuit 120, the printed circuit 120 is used to replace conventional heat conductive tubes for heat transfer. Heat generated from each heat source 110 on the circuit board 100 is transferred to the thermal conductive area 122 via the printed circuit 120. The cooling structure 200 on the thermal conductive area 122 then radiates the heat into surrounding space by radiation. As a result, the heat can be transferred and dissipated away without the use of additional heat conductive elements and the need of changing circuit layouts.

It is to be understood that the above descriptions are merely the preferable embodiments of the present invention and are not intended to limit the scope of the present invention. Equivalent changes and modifications made in the spirit of the present invention are regarded as falling within the scope of the present invention.

What is claimed is:

1. A radiative cooling structure for a printed circuit, comprising:
a circuit board, a printed circuit being disposed on the circuit board, the printed circuit including a plurality of printed leads and a thermal conductive area, the printed leads being connected to the thermal conductive area; and
a cooling structure covering the thermal conductive area, the cooling structure including a thermal radiation layer.

2. The radiative cooling structure for the printed circuit according to claim 1, wherein an adhesive layer is sandwiched between the thermal radiation layer and the circuit board.

3. The radiative cooling structure for the printed circuit according to claim 1, wherein the thermal radiation layer is in a sheet form and consists of a thermal radiation material.

4. The radiative cooling structure for the printed circuit according to claim 3, wherein the thermal radiation layer consists of a graphene sheet.

5. The radiative cooling structure for the printed circuit according to claim 4, wherein the thermal radiation layer consists of a single graphene sheet.

6. The radiative cooling structure for the printed circuit according to claim 4, wherein the thermal radiation layer consists of a plurality of graphene sheets joined to each other to extend.

7. The radiative cooling structure for the printed circuit according to claim 1, wherein the thermal radiation layer includes a fixing structure and a plurality of thermal radiation particles scattered and embedded in the fixing structure.

8. The radiative cooling structure for the printed circuit according to claim 7, wherein the thermal radiation particle is a graphene fragment.

9. The radiative cooling structure for the printed circuit according to claim 7, wherein the thermal radiation particle is a nano-carbon ball.

10. The radiative cooling structure for the printed circuit according to claim 7, wherein the fixing structure consists of a cured gel material.

11. The radiative cooling structure for the printed circuit according to claim 1, wherein the thermal conductive area is a ground of the printed circuit.

12. The radiative cooling structure for the printed circuit according to claim 1, wherein the thermal conductive area is exposed from one surface of the circuit board.

13. The radiative cooling structure for the printed circuit according to claim 1, wherein at least one heat source is disposed on the circuit board, and the printed leads are connected between the thermal conductive area and any of the heat sources.
